(19) United States
(12) Patent Application Publication
(10) Pub. No.: US 2008/0042884 A1
(43) Pub. Date: Feb. 21, 2008

(54) KEYBOARD WITH WIRELESS ELECTRONIC DEVICE

(75) Inventors: Fong-Chi Hsu, Taipei Hsien (TW); Feng-Ting Hsu, Taipei Hsien (TW); Jung-Yu Peng, Taipei Hsien (TW)

Correspondence Address: J C PATENTS, INC., 4 VENTURE, SUITE 250, IRVINE, CA, 92618, US

(73) Assignee: JENSIN INTL TECHNOLOGY CORP., Taipei County (TW)

(21) Appl. No.: 11/839,271

(22) Filed: Aug. 15, 2007

(30) Foreign Application Priority Data
Aug. 21, 2006 (TW) 95214769

(51) Int. Cl. H03M 11/00

(52) U.S. Cl. 341/22

(57) ABSTRACT

A keyboard with wireless electronic device is provided. The present invention includes a body, a first transceiver and a wireless electronic device. The body includes a plurality of keys and a circuit board. The circuit board has a plurality of signal contacts corresponding to the keys. The first transceiver is disposed in the body. The wireless electronic device includes a second transceiver. The first transceiver and the second transceiver transfer voice packets to each other in the same radio frequency range.

### CROSS-REFERENCE TO RELATED APPLICATION

This application claims the priority benefit of Taiwan application serial no. 95214769, filed Aug. 21, 2006. All disclosure of the Taiwan application is incorporated herein by reference.

### BACKGROUND OF THE INVENTION

1. Field of the Invention

The present invention relates to a computer peripheral equipment. More particularly, the present invention relates to a keyboard with at least a wireless electronic device.

2. Description of Related Art

Along with the development of technology, computers have become broadly used and indispensable in our daily life. To allow users to store data conveniently into personal computers, personal computers are usually equipped with keyboards for inputting data and commands.

FIG. 1 is a perspective diagram of a conventional keyboard. Referring to FIG. 1, the keyboard 100 has a plurality of keys 102 arranged in an array. A user inputs data or commands to the computer (not shown) by pressing the keys 102 on the baseboard 110.

FIG. 2 is an enlarged diagram of a key assembled on the base board in FIG. 1. As shown in FIG. 2, each key 102 includes a key cap 104 which is fixed on the base board 110 by a supporting structure 106. A circuit board 108 is disposed on the base board 110, and the signal contact 108a on the circuit board 108 has an elastic bump 108b protruded from the supporting structure 106 to be in contact with the bottom of the key cap 104. When a user presses the key 102, the key 102 will contact and push down the elastic bump 108b so that the signal contacts 108a on the circuit board 108 are electrically connected each other and enabled to turn on; accordingly, the corresponding circuit operation is started up.

A conventional keyboard can only be used for inputting text information. However, today's computers have more diverse functions, and a user can receive information from a computer through other electronic devices, for example, a user can make phone calls over network phone or transfer files to a MP3 player from a computer, etc.

### SUMMARY OF THE INVENTION

Accordingly, the present invention is directed to provide a keyboard with wireless electronic device, wherein a user can transfer information between a computer and the wireless electronic device through the keyboard when using the computer.

To achieve the aforementioned and other objectives, the present invention provides a keyboard with wireless electronic device. The keyboard includes a body, a first transceiver, and a wireless electronic device. The body has a plurality of keys and a circuit board, and the circuit board has a plurality of signal contacts corresponding to the keys. The first transceiver is disposed in the body. The wireless electronic device has a second transceiver. The first transceiver and the second transceiver transfer voice packets to each other in the same radio frequency range.

According to an embodiment of the present invention, the keys include a default key for turning on/off the first transceiver.

According to an embodiment of the present invention, the first transceiver and the second transceiver also transfer data packets to each other in the same radio frequency range.

According to an embodiment of the present invention, the data packets include a network phone number or SMS (short message service).

According to an embodiment of the present invention, the wireless electronic device includes a display for displaying the data packet transferred by the first transceiver.

According to an embodiment of the present invention, the wireless electronic device includes a plurality of input keys for inputting the data packet transferred by the second transceiver.

According to an embodiment of the present invention, the wireless electronic device includes a network phone.

According to an embodiment of the present invention, the wireless electronic device includes a MP3 player.

According to an embodiment of the present invention, the wireless electronic device includes a wireless headset.

According to an embodiment of the present invention, the body further has a bus transmission cable electrically connected to the circuit board and the first transceiver.

According to an embodiment of the present invention, the first transceiver and the second transceiver include Bluetooth wireless transceivers, wireless universal serial bus (WUSB) transceivers, wireless IEEE 1394 transceivers, or IEEE 802.11n wireless local-area network (WLAN) transceivers.

According to the present invention, a keyboard is integrated with another wireless electronic device so that a user can receive information from the computer through the keyboard. Moreover, the data is transmitted between the keyboard and the wireless electronic device in wireless manner, thus, the user can use the wireless electronic device more conveniently when the user operates the computer through the keyboard.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a perspective diagram of a conventional keyboard.

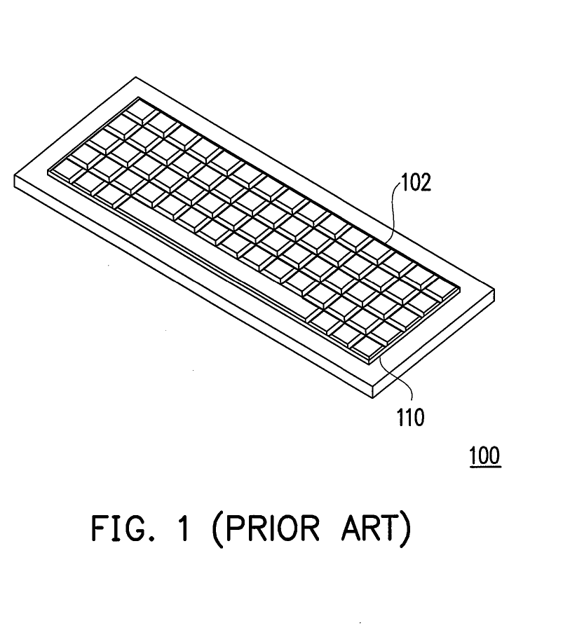

FIG. 2 is an enlarged diagram of a key disposed on the base board in FIG. 1.

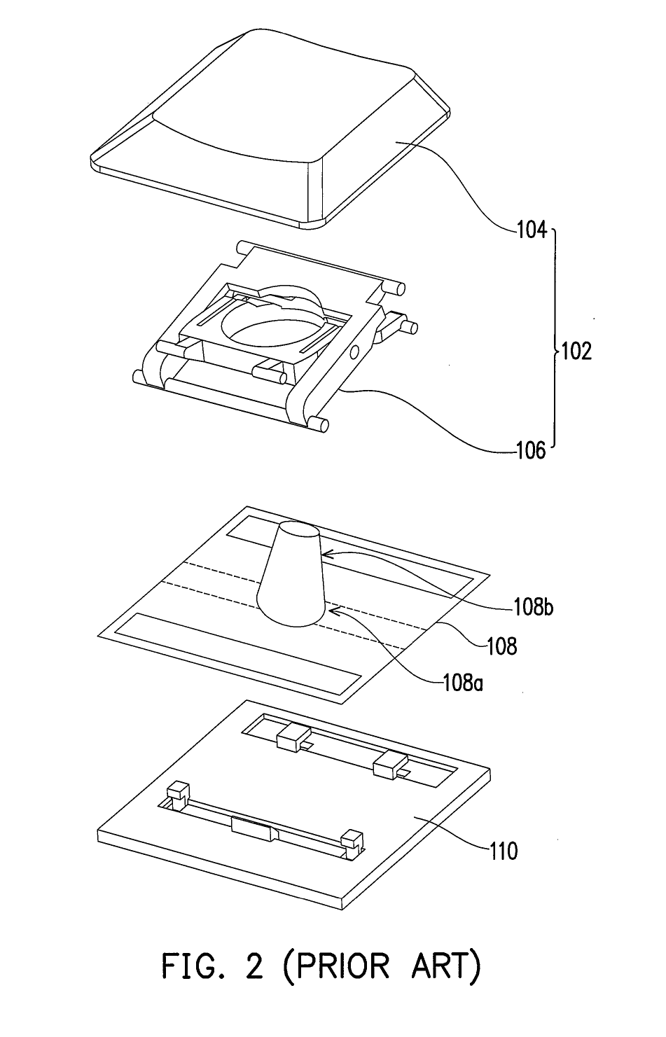

FIG. 3 is a diagram of a keyboard with a wireless electronic device in the present invention.

### DESCRIPTION OF EMBODIMENTS

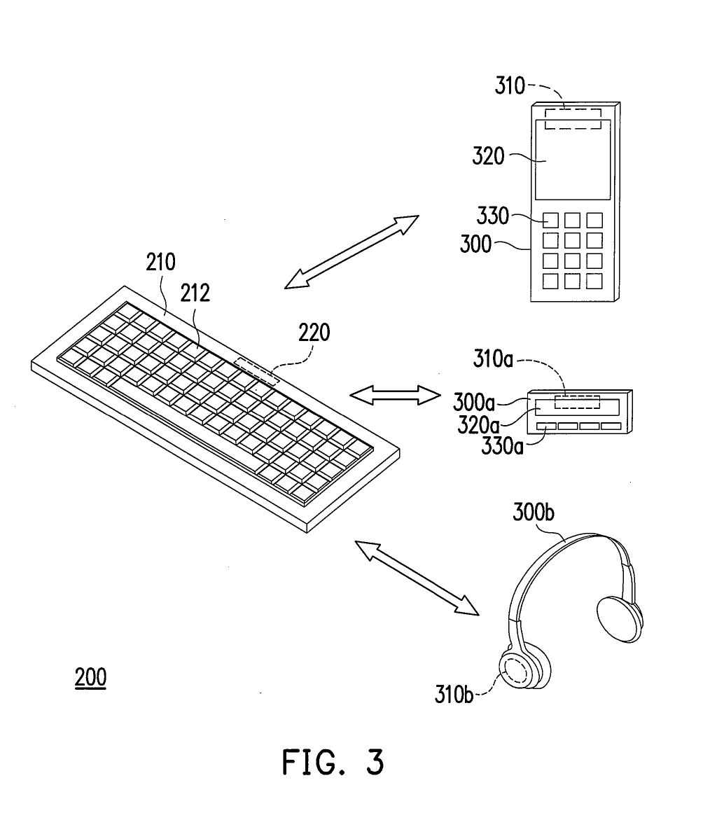

FIG. 3 is a diagram of a keyboard with a wireless electronic device in the present invention. Referring to FIG. 3, the keyboard 200 with wireless electronic device includes a body 210, a first transceiver 220 and a wireless electronic device 300. The body 210 has a plurality of keys 212 and a circuit board (not shown). The circuit board has a plurality of signal contacts (not shown) corresponding to the keys. When a key 212 is pressed down, the signal contacts on the circuit board corresponding to the key 212 are connected to each other and enabled to turn on. Please refer to the description of the conventional keyboard for the details of the keys, the circuit board, and the signal contacts, which will not be described herein.

As described above, the first transceiver 220 is disposed in the body 210. The wireless electronic device 300 has a second transceiver 310. The first transceiver 220 and the second transceiver 310 transfer voice packets to each other in the same radio frequency range. The first transceiver 220 and the second transceiver 310 transfer information to each other in wireless manner so that the user can use the wireless electronic device 300 conveniently. In addition, one of the keys 212 can be set as a default key (not shown) automatically by a software or manually by the user, and the user can control the switch of the first transceiver 220 through the default key, which is, turning off the first transceiver 220 through the key 212 when the wireless electronic device 300 is not used and turning on the first transceiver 220 when the wireless electronic device 300 is in use.

The body 210 further includes a bus transmission cable (not shown) electrically connected to the circuit board and the first transceiver 220. The bus transmission cable allows the body 210 and a computer (not shown) to transfer voice information or other data to each other, and the wireless electronic device 300 and the computer transfer voice information and other data to each other through the first transceiver 220, the second transceiver 310, and the bus transmission cable. The bus transmission cable can be implemented for cable transmission, such as a PS/2 connector or a USB, or for wireless transmission, such as a Bluetooth wireless transceiver.

Besides the aforementioned voice packets, the wireless electronic device 300 and the body 210 may also transfer other data packets to each other in the same radio frequency range. The wireless electronic device 300 is an electronic device which can be used with a computer, such as a network phone, an MP3 player, etc. In the present embodiment, the wireless electronic device 300 is a network phone having a display 320 and a plurality of input keys 330. The wireless electronic device 300 may be used for receiving/sending SMS(short message service) message or making network phone calls.

To be specific, when sending an SMS, the user inputs the information to be transmitted through the input keys 330, and then the second transceiver 310 transfers the SMS message as a data packet to the first transceiver 220. During receiving the short message, the body 210 transfers a received SMS message as a data packet to the second transceiver 310 through the first transceiver 220, and the display 320 displays the data packet sent by the first transceiver 220.

As described above, when making a network phone call, the user can transfer or receive a network phone number by the same means of sending/receiving a SMS message. After the user dials the phone number to make a phone call or picks up a phone call through the input keys 330, the wireless electronic device 300 and the first transceiver 220 of the body 210 transfer voice packets to each other through the second transceiver 310, and the body 210 and the computer transfer voice information to each other through the bus transmission cable, so that the user can converse with another party through voice over IP (VoIP). Since wireless transmission is adopted between the wireless electronic device 300 and the body 210, the user will not be restricted by the transmission cable therebetween when making phone calls or sending/receiving SMS message.

In the foregoing embodiment, the first transceiver 220 and the second transceiver 310 may be Bluetooth wireless transceivers, or other wireless transmission equipment such as WUSB transceivers, wireless IEEE 1394 transceivers, or IEEE 802.11n wireless local area network (WLAN) transceivers. The first transceiver 220 and the second transceiver 310 are not limited herein as long as the first transceiver 220 and the second transceiver 310 can perform wireless communication.

Even though a network phone is described above as an example of the wireless electronic device 300 in the present invention, the wireless electronic device 300 is not limited in the present invention, and other wireless electronic devices may also be used by those skilled in the art. In another embodiment of the present invention, the wireless electronic device 300a may be an MP3 player having a display 320a and a plurality of input keys 330a. The user can see information received by the wireless electronic device 300a from the display 320a and can operate the wireless electronic device 300a by using the input keys 330a to record or play music and to transfer MP3 files between the wireless electronic device 300a and the computer through the body 210.

In yet another embodiment of the present invention, the wireless electronic device 300b is a wireless headset (earphone with a microphone). The wireless electronic device 300b and the second transceiver 310 of the body 210 transfer voice packets to each other through the second transceiver 310b, and the body 210 and the computer transfer voice information to each other through the bus transmission cable, so that the user can transfer voice data between the computer and the wireless electronic device 300b. In addition, the number of wireless electronic devices is not limited in the present invention, and those skilled in the art should be able to integrate a plurality of wireless electronic devices having identical or different functions with the keyboard body 210.

In overview, according to the present invention, a keyboard is integrated with an electronic device so that a user can transfer information to the wireless electronic device through the keyboard besides inputting text information through the keyboard. Moreover, since wireless transmission is adopted between the keyboard body and the electronic device, the user can operate the computer and use the wireless electronic device through the keyboard at the same time. Besides, the first transceiver is disposed in the body so that the user can control the switch of the first transceiver by using a default key on the keyboard.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A keyboard with wireless electronic device, comprising:
a body, having a plurality of keys and a circuit board, the circuit board having a plurality of signal contacts corresponding to the keys;
a first transceiver, disposed in the body; and
a wireless electronic device, having a second transceiver, wherein the first transceiver and the second transceiver transfer voice packets to each other in a same radio frequency range.

2. The keyboard as claimed in claim 1, wherein one of the keys comprises a default key for turning on/off the first transceiver.

3. The keyboard as claimed in claim 1, wherein the first transceiver and the second transceiver comprise radio data transceivers for transferring data packets to each other.

4. The keyboard as claimed in claim 3, wherein the data packet comprises a network phone number or a SMS (short message service) message.

5. The keyboard as claimed in claim 3, wherein the wireless electronic device comprises a display for displaying the data packet transferred by the first transceiver.

6. The keyboard as claimed in claim 1, wherein the wireless electronic device comprises a plurality of input keys for inputting a data packet to be transferred by the second transceiver.

7. The keyboard as claimed in claim 1, wherein the wireless electronic device comprises a network phone.

8. The keyboard as claimed in claim 1, wherein the wireless electronic device comprises a MP3 player.

9. The keyboard as claimed in claim 1, wherein the wireless electronic device comprises a wireless headset.

10. The keyboard as claimed in claim 1, wherein the body further comprises a bus transmission cable electrically connected to the circuit board and the first transceiver.

11. The keyboard as claimed in claim 1, wherein the first transceiver and the second transceiver comprise Bluetooth wireless transceivers, wireless universal serial bus (WUSB) transceivers, wireless IEEE 1394 transceivers, or IEEE 802.11n wireless local-area network (WLAN) transceivers.
